(19) United States
(12) Patent Application Publication
(10) Pub. No.: US 2011/0278478 A1
(43) Pub. Date: Nov. 17, 2011

(54) METHOD AND IMPLANTER FOR IMPLANTING A WORKPIECE

(76) Inventor: Causon Ko-Chuan JEN, San Jose, CA (US)

(21) Appl. No.: 12/781,608

(22) Filed: May 17, 2010

(51) Int. Cl. H01J 37/317

(52) U.S. Cl. 250/492.21; 250/492.3

(57) ABSTRACT

To form one or more dose region(s) on a workpiece, a projected area of an ion beam on the workpiece is initially moved parallel to a long axis of the projected area from an edge of the workpiece to an opposite edge of the workpiece, and then is moved parallel to a short axis of the projected area a shifted distance shorter than the short axis of the projected area. Thereafter, repeat the moving step and the shifting step in sequence until all dose region(s) is completely formed. Accordingly, the cross-sectional size of the projected area is only proportional to the short axis when it is moved along its long axis. Hence, it is similar to use a narrow pen to paint a wall, and then it is suitable for forming different dose regions with different doses on a workpiece, such as the dose split.

### FIELD OF THE INVENTION

The present invention generally relates to a method and an implanter for implanting a workpiece, and more particularly to a method and an implanter for implanting a workpiece having some dose regions with different doses.

### DESCRIPTION OF THE RELATED ART

Ion implantation is a process of depositing chemical species into a workpiece, such as a silicon wafer or a glass panel, by directly bombarding numerous energized ions with specific mass-to-charge ratio into the workpiece. In semiconductor fabrication, ion implantation is used primarily for doping process that alters the type and the level of conductivity of target materials. A precise doping profile in a workpiece is often crucial for proper integrated circuit performance.

Conventional, all dose regions on a workpiece correspond to one and only one dose. Hence, the workpiece is uniformly implanted by an ion beam after the workpiece is thoroughly scanned by the ion beam. Two well-known approaches are the one-dimensional scan and the two-dimensional scan. As shown in FIG. 1A, in the former approach, a relative movement between a workpiece 10 and an ion beam 11 is made along a one-dimensional scan line 12, wherein the beam height of the ion beam 11 is larger than the diameter of the workpiece 10. Undoubtfully, the continuous increase in the size of the workpiece 10 correspondingly increases the cost and difficulty of providing the ion beam 11 with enough beam height, uniformity and stability. Hence, the current semiconductor fabrication popularly uses the latter approach so that a uniform implantation and a high throughput can be achieved simultaneously. As shown in FIG. 1B, in the latter approach, a relative movement between the workpiece 10 and the ion beam 11 is made along a raster pattern 13 so that whole workpiece 10 is scanned by the ion beam 11. Herein, the raster pattern 13 has N mutually parallel and spaced scan lines 14₁ to 14ₙ, wherein N is the number of the scan lines The relative movement is formed by the following steps: moving the workpiece 10 along the first scan line 14₁ parallel to the X-axis direction until the workpiece 10 is completely clear of the ion beam 11, shifting the workpiece 10 down along the Y-axis direction, moving the workpiece 10 backwards along the second scan line 14₂ parallel to the X-axis direction until the workpiece 10 is completely clear of the ion beam 11 again, shifting the workpiece 10 down along the Y-axis direction again, and so on until the whole workpiece 10 has seen the ion beam 11. Significantly, the total period of moving the workpiece 10 completely through the raster pattern 13 is proportional to the number of the scan lines, i.e., inversely proportional to the step distance (i.e., the scan path pitch) between any neighboring scan lines 14x, x is a positive integer not larger than N. Hence, to maximize the throughput and maintain the implantation uniformity simultaneously, the long axis of the projected area of the ion beam 11 on the workpiece 10 is arranged to be parallel to the Y-axis and then the upper limitation of the step distance in the conventional skill is the beam height of the ion beam 11. Reasonably, the advantage is more significant when the beam height of the ion beam 11 is increased.

However, some new commercial applications require two or more dose regions on a workpiece having separate doses, i.e., non-uniform implantation over a workpiece. For example, the dose split that some dose regions on a workpiece are implanted separately by using different implant parameters' values. The dose split may be applied to form some similar chips with same layout but different doses on a workpiece simultaneously for testing which dose is better

Reasonably, the conventional approaches are at a big disadvantage when they are used to non-uniformly implant a workpiece. For example, as shown in FIG. 1C and FIG. 1D, when one specific dose region 17 has an axis parallel to and shorter than the long axis of a projected area 16 of the ion beam 11 on the workpiece 10, the projected area 16 moved through the specific dose region 17 along a specific scan line 15 will be partially projected outside the specific dose region 17, even will be partially implanted into other neighboring dose region(s) 17. Herein, the specific scan line 15 is a portion of the raster pattern 13 used by the conventional two-dimensional scan. Of course, sometimes, these disadvantages may be solved by rotating the workpiece 10 to change the relative geometric relation between the specific dose region 17 and the projected area 16. However, as usual, it is hard to find a proper rotation that all dose regions 17 on the rotated workpiece 10 has no axis parallel to and shorter than the long axis of the projected area 16 and all dose regions may be separately scanned by the projected area 16 in sequence.

To solve these disadvantages, a mask may be used to cover partial workpiece so that the ion beam will only be implanted into the dose region right be scanned, a beam optics may be used to deform the ion beam after the mass analyzer so that both the shape and the size of the projected area is adjusted to just fit the dose region right be scanned, or several implant processes may be performed in sequence to produce the required dose region by combining different implant results on the same workpiece. Significantly, all these skills require extra step(s) and/or extra device(s), and then higher cost and more difficulties are unavoidable. Therefore, there is still a need to find a novel method and a novel implanter for non-uniformly implanting a workpiece effectively and economically.

### SUMMARY OF THE INVENTION

A method and an implanter capable of implanting a workpiece having some dose regions with different doses are proposed. The essential mechanism of the proposed method and the proposed implanter is briefly disclosed as below. To form one or more dose regions on a workpiece, a projected area of an ion beam on the workpiece may be initially moved parallel to a long axis of the projected area from an edge of the workpiece to an opposite edge of the workpiece, and then may be moved parallel to a short axis of the projected area a shifted distance shorter than the short axis of the projected area. Thereafter, repeat the moving step and the shifting step in sequences until a portion of the workpiece is completely scanned by the projected area so that one or more dose regions are formed on the scanned portion.

Significantly, one main difference between the essential mechanism of the proposed method/implanter and the conventional two-dimensional scan is the direction of the projected area during a period of moving the projected area over the workpiece. In the conventional two-dimensional scan, the long axis of the projected area is essentially vertical to a scan line when the projected area is moved along the scan line through the workpiece. In contrast, in the invention, the long axis of the projected area is essentially parallel to a scan line when the projected area is moved along the scan line through the workpiece. In other words, the conventional two-dimensional scan may be viewed as using a wide pen paint a wall along a raster pattern over the wall, but the invention should be viewed as using a narrow pen to paint the wall along another raster pattern over the wall. Herein, in the invention, the upper limitation of the width of the narrow pen is the size of the short axis of the projected area.

Accordingly, some conventional disadvantages of the non-uniform implantation over a workpiece can be improved. For example, even the projected area is moved along a scan line close to an edge of a dose region, the probability that partial ion beam is implanted into a portion of the workpiece outside the dose region may be reduced because the width of the projected area is limited by the size of its short axis but not the size of its long axis. Further, even two dose regions are close to each other, the probability that the projected area partially overlapped with both dose regions also may be reduced. For example, for the dose split, different dose regions with different doses can be respectively formed in sequence when a projected area of an ion beam is moved along numerous spaced lines parallel to the long axis of the projected area through the workpiece in sequence. Herein, because the projected area essentially will not overlap with two or more neighboring dose regions simultaneously, one or more scan parameter's value(s) may be respectively adjusted so that different dose regions may have different doses. For example, different dose regions may be formed respectively by using different scan velocities, different sizes of the projected area, different step distance, and so on.

One embodiment provides a method of implanting a workpiece by an ion beam. Initially, provide an ion beam and a workpiece with some mutually parallel dose regions. Next, project the ion beam on the workpiece to form a projected area of the ion beam, wherein the projected area has a long axis and a short axis. Then, move the projected area along a first line essentially parallel to the long axis from an edge of the workpiece to an opposite edge of the workpiece. And then, shift the projected area along a second line essentially parallel to the short axis with a shifted distance not larger than a size of the short axis. After that, repeatedly move and shift the workpiece in sequence until all the dose regions are completely scanned by ion beam.

Another embodiment provides a method of implanting a workpiece by an ion beam. Initially, provide a workpiece and an ion beam. Herein, the workpiece has a dose region shaped by two mutually parallel straight lines crossing the workpiece, a cross section of the ion beam has a long axis and a short axis, and the long axis is shorter than a vertical distance between the mutually parallel straight lines. Then, move the workpiece across the ion beam along a first line essentially parallel to the long axis. Next, shift the workpiece along a second line essentially parallel to the short axis with a shifted distance not larger than a size of the short axis. After that, repeatedly move and shift the workpiece in sequence until whole the dose region is scanned by ion beam.

The other embodiment provides an implanter capable of implanting a workpiece by an ion beam. The implanter has at least an ion beam projection assembly capable of providing an ion beam and a movement assembly capable of moving a workpiece. The implanter further has a controller capable of controlling one or more of the movement assembly and the ion beam projection assembly so that one or more dose regions on the workpiece are completely scanned by a projected area of the ion beam on the workpiece by repeating the below steps in sequence: moving the projected area along a first line essentially parallel to a long axis of the projected area from an edge of the workpiece to an opposite edge of the workpiece; and shifting the projected area along a second line essentially parallel to a short axis of the projected area with a shifted distance not larger than a size of the short axis.

### BRIEF DESCRIPTION OF THE DRAWINGS

FIG. 1A to FIG. 1B schematically illustrate how a workpiece is implanted by an ion beam according to the conventional one-dimensional scan and the conventional two-dimensional scan respectively;

FIG. 1C to FIG. 1D schematically illustrate some disadvantages of the conventional two-dimensional scan as a non-uniform implantation over a workpiece is required;

FIG. 2A to FIG. 2E schematically illustrates how a workpiece is implanted by an ion beam according to an embodiment of the invention;

FIG. 3 is a flowchart of a method for implanting a workpiece by an ion beam according to another embodiment of the invention;

FIG. 4A to FIG. 4D schematically illustrate how to realize the dose split by the proposed invention;

FIG. 5A to FIG. 5B schematically illustrates two potential definition of the long axis and the short axis of an projected area;

FIG. 6 schematically illustrates a potential implanter according to the proposed invention;

FIG. 7 schematically illustrates another potential implanter according to the proposed invention; and

FIG. 8 schematically illustrates the other potential implanter according to the proposed invention.

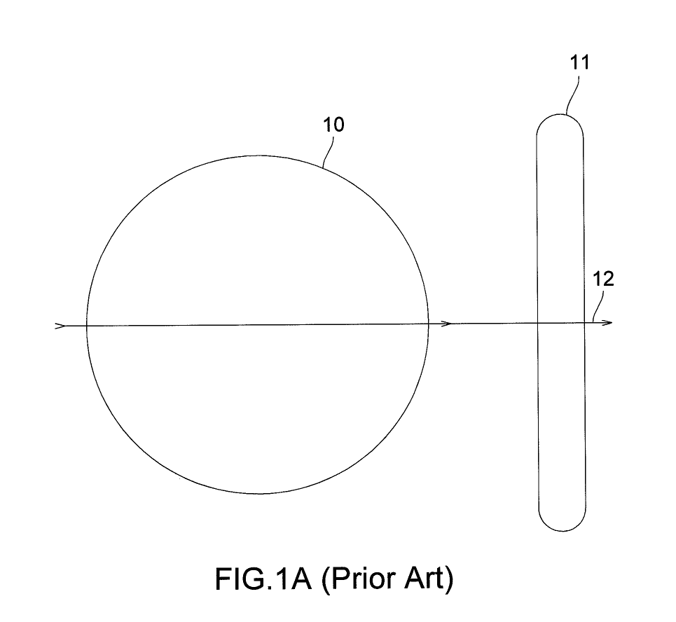

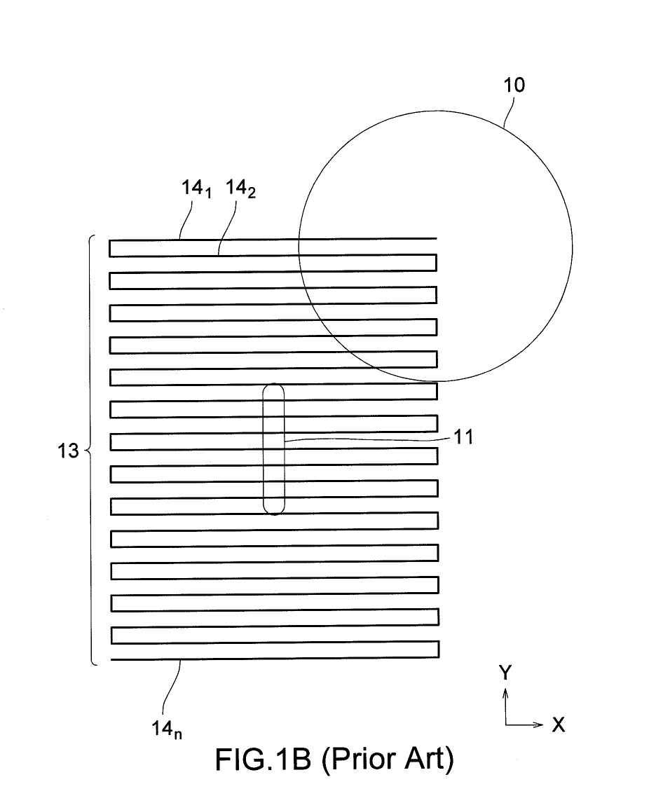

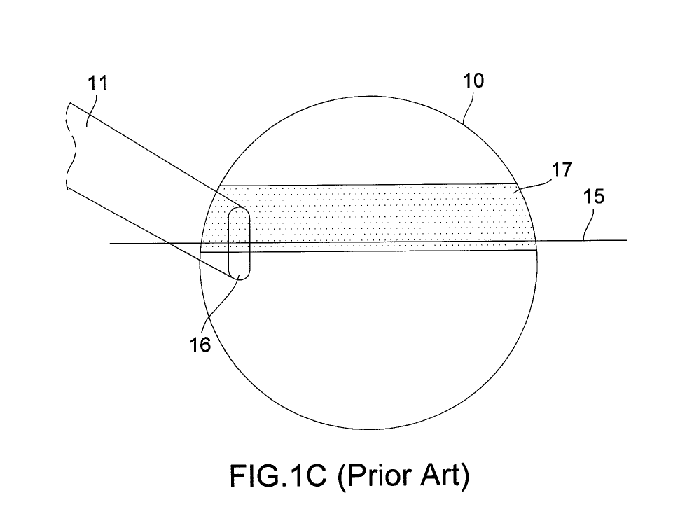

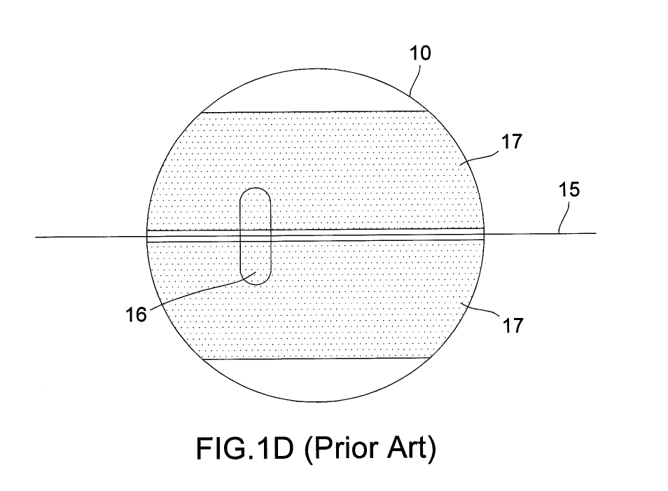

### DETAILED DESCRIPTION OF THE INVENTION

Reference will now be made in detail to specific embodiments of the present invention. Examples of these embodiments are illustrated in the accompanying drawings. While the invention will be described in conjunction with these specific embodiments, it will be understood that it is not intended to limit the invention to these embodiments. In fact, it is intended to cover alternatives, modifications, and equivalents as may be included within the spirit and scope of the invention as defined by the appended claims. In the following description, numerous specific details are set forth in order to provide a through understanding of the present invention. The present invention may be practiced without some or all of these specific details. In other instances, well-known process operations are not described in detail in order not to obscure the present invention.

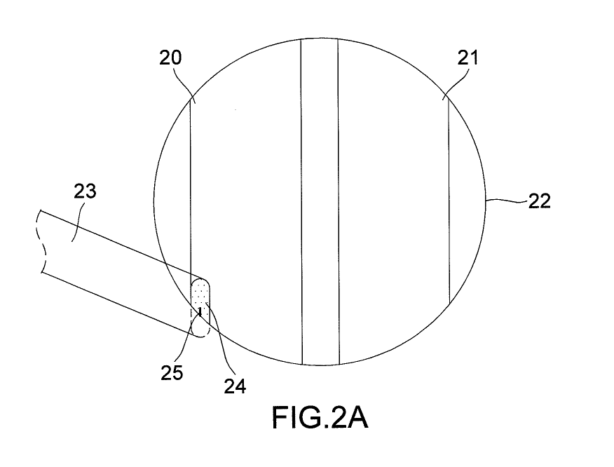

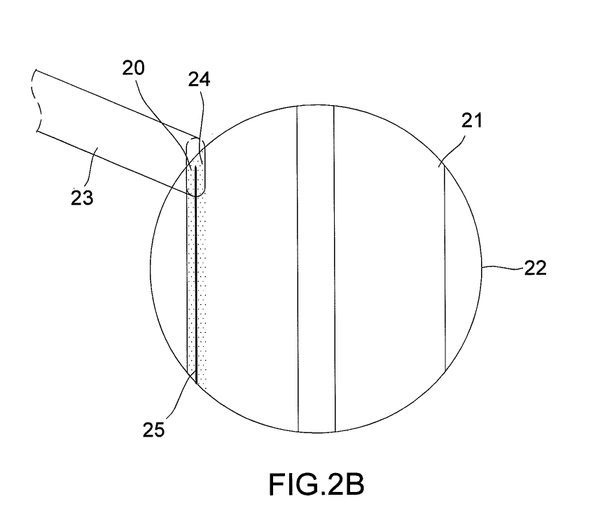

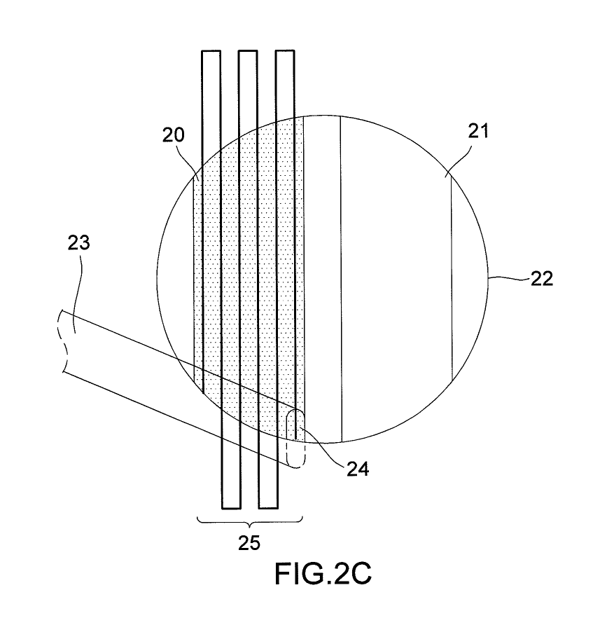

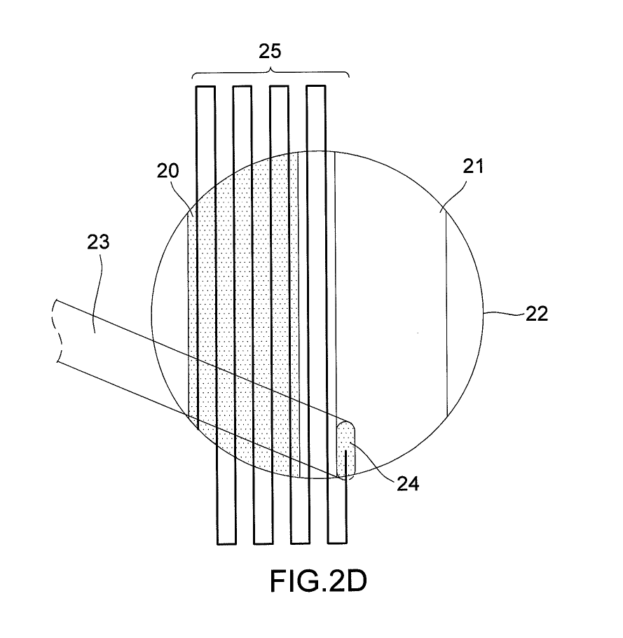

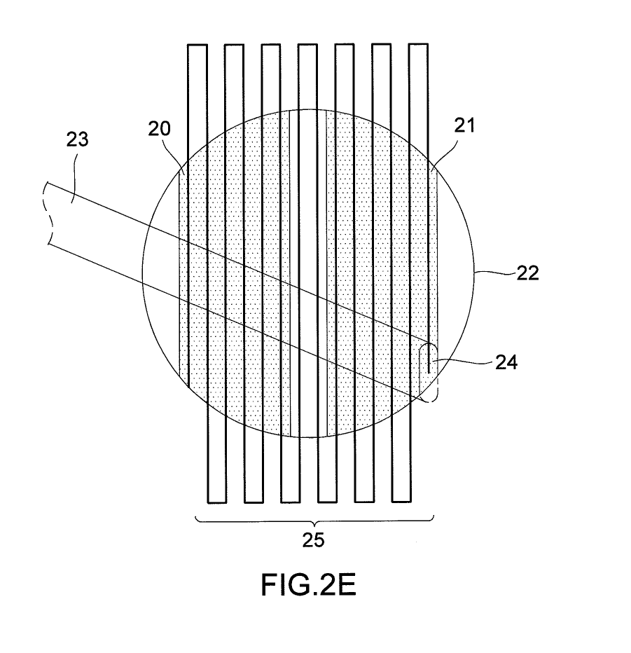

One embodiment of the invention is a method of implanting a workpiece by an ion beam. Initially, a workpiece and an ion beam are provided. Herein, the workpiece has a dose region shaped by two mutually parallel straight lines crossing the workpiece, and a cross section of the ion beam has a short axis and a long axis being shorter than a vertical distance between the mutually parallel straight lines. Then, the workpiece is moved across the ion beam along a first line essentially parallel to the long axis. Next, the workpiece is shifted along a second line essentially parallel to the short axis, wherein a shifted distance is not larger than a size of the short axis. After that, the foregoing moving step and shifting step are repeated in sequence until whole the dose region is scanned by the ion beam. One potential application of the embodiment is shown in FIG. 2A to FIG. 2E, wherein the dose region 20 and the dose region 21 on the workpiece 22 are scanned separately by the ion beam 23 when the projected area 24 of the ion beam 23 on the workpiece 22 is moved along a raster pattern 25 completely through the dose region 20 and the dose region 21 in sequence.

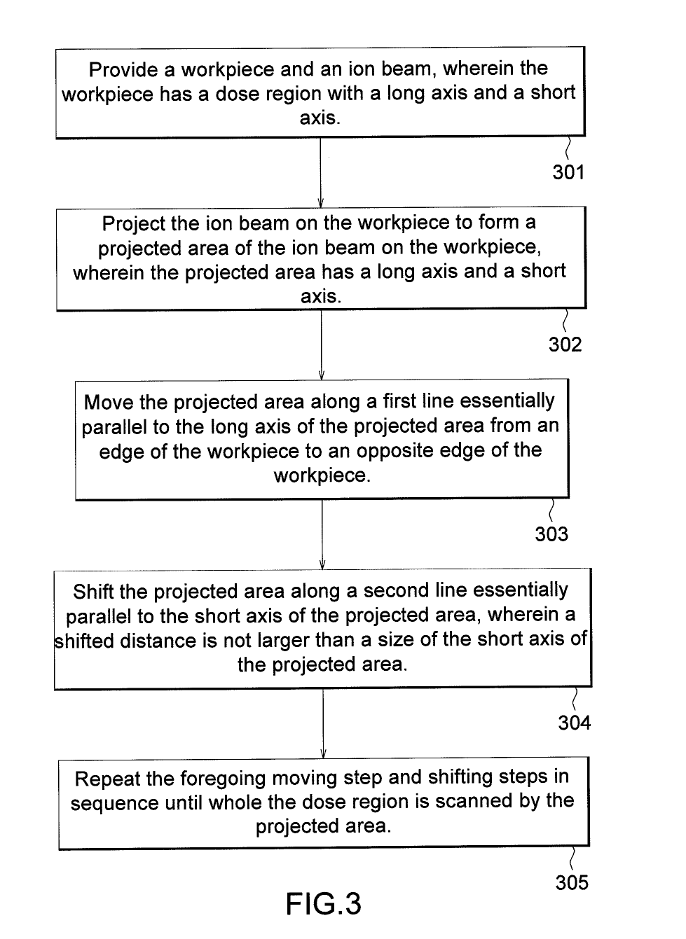

Another embodiment is a method of implanting a workpiece by an ion beam, as shown in blocks 301˜305 of FIG. 3. Initially, provide a workpiece and an ion beam, wherein the workpiece has a dose region with a long axis and a short axis. Next, project the ion beam on the workpiece to form a projected area of the ion beam on the workpiece, wherein the projected area has a long axis and a short axis. Then, move the projected area along a first line essentially parallel to the long axis of the projected area from an edge of the workpiece to an opposite edge of the workpiece. And then, shift the projected area along a second line essentially parallel to the short axis of the projected area, wherein a shifted distance is not larger than a size of the short axis of the projected area. After that, repeat the foregoing moving step and shifting steps in sequence until whole the dose region is scanned by the projected area.

By comparing with the conventional two-dimensional scan, one main characteristic of these embodiments is that the projected area of the ion beam is moved between opposite edges of the workpiece along one or more spaced lines parallel to the long axis of the projected area. In contrast, in the conventional two-dimensional scan, the projected area of the ion beam is moved between opposite edges of the workpiece along one or more spaced lines parallel to the short axis of the projected area. Note that the main characteristic is independent on the geometric shape of the dose region and also is independent on the geometric shape relation between the dose region and the projected area. Although in the practical applications of the foregoing embodiments, the long axis of the projected area usually is essentially parallel to the long axis of the dose region to maximize the efficiency. Furthermore, these embodiments can be viewed as that a narrow pen is used to paint the wall along a raster pattern over the wall, but the conventional two-dimensional scan can be viewed as that a wide pen is used to paint a wall along another raster pattern over the wall. Reasonably, the upper limitation of the width of the narrow pen is the size of the short axis of the projected area, and the upper limitation is not larger than the long axis of the projected area. Therefore, different portions of the workpiece (or viewed as the wall) can be flexibly and efficiently scanned (or viewed as painted) by the ion beam projected area (or viewed as the pen), because a narrow pen is more suitable to paint a narrow portion of a wall and to paint respectively some close neighboring portions of a wall.

Accordingly, these embodiments may improve some disadvantages of the conventional two-dimensional scan. For example, even the projected area of an ion beam is moved along a scan line parallel to and close to an edge of a dose region on a workpiece, the probability that partial ion beam is implanted into a portion of the workpiece outside the dose region can be minimized. Note that only partial workpiece located on the neighborhood of the scan line with a distance from the scan line not larger than half of the size of short axis of the projected area will be scanned by the projected area. For example, even two dose regions are close to each other, the probability that the projected area partially overlapped with both dose regions still is zero except the distance between the two dose regions is shorter than half of the size the short axis of the projected area.

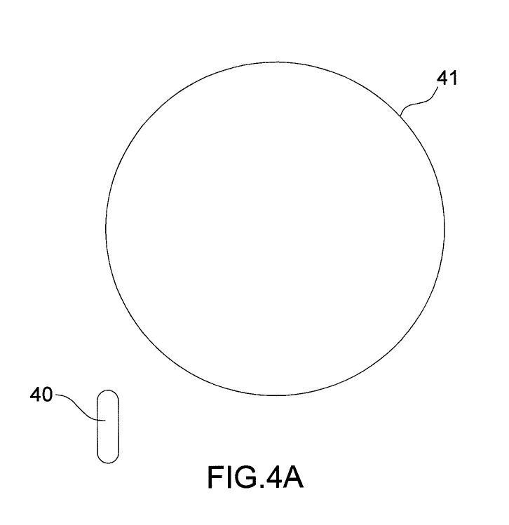

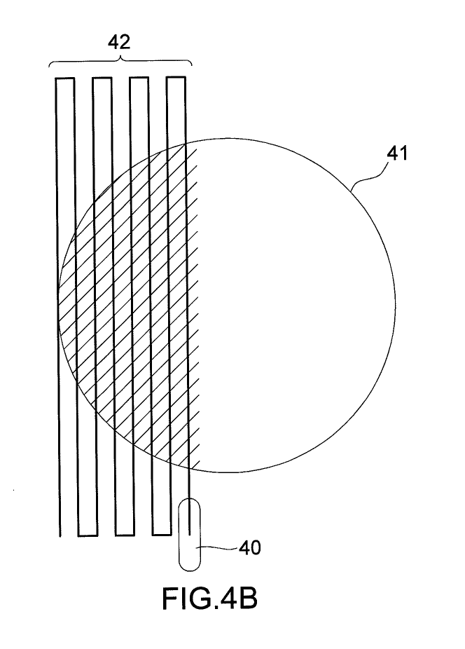

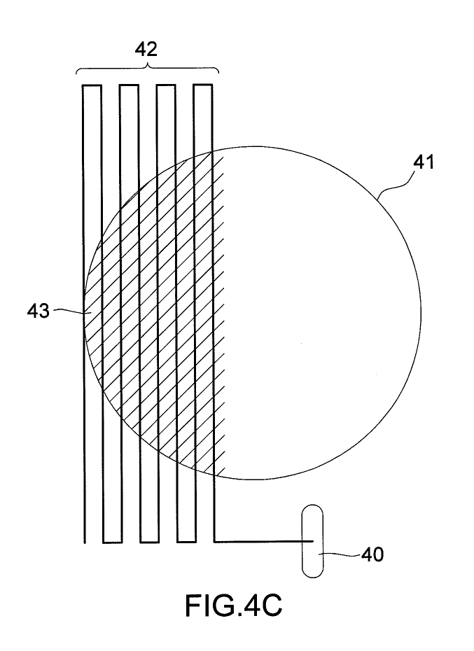

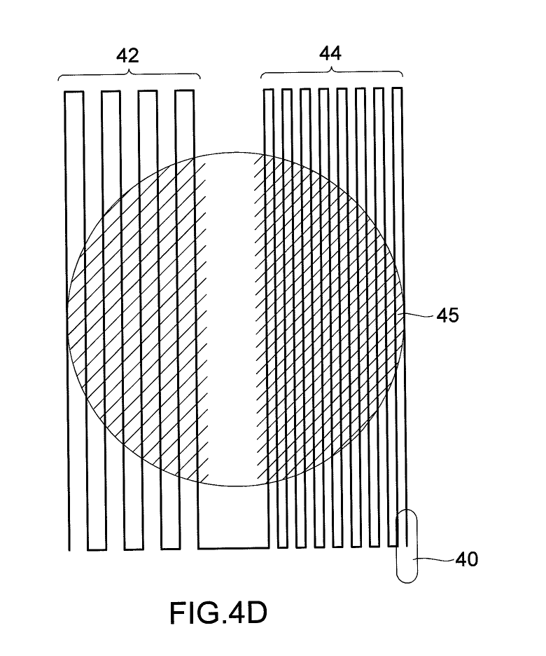

One important application of the invention is the dose split where some dose regions with different doses are separately disposed on a workpiece. Initially, as shown in FIG. 4A, ion beam 40 and workpiece 41 are provided. Next, as shown in FIG. 4B, the workpiece 41 is moved along a first raster pattern 42 with a first set of scan parameters' values so that a first portion of the workpiece 41 is completely scanned by the ion beam 40 and transformed into a first dose region 43. Herein, the first raster pattern 42 has several mutually parallel spaced scan lines overlapped with the first portion, and each scan line is parallel to the long axis of the cross section of the ion beam 40. Herein, the workpiece 41 is moved along through these scan lines in sequence. Then, as shown in FIG. 4C, the relative position between the workpiece 41 and the ion beam 40 is changed so that the ion beam 40 is close to another portion of the workpiece 41. Herein, how the relative position is changed is not limited, it may be achieved by moving the workpiece 41 along another raster pattern or by directly moving the workpiece 41 along a straight line. And then, as shown in FIG. 4D, the workpiece 41 is moved along a second raster pattern 44 with a second set of scan parameters' values so that a second portion of the workpiece 41 is completely scanned by the ion beam 40 and transformed into a second dose region 45. Herein, the second raster pattern 44 has several mutually parallel spaced scan lines overlapped with the second portion, and each scan line is parallel to the long axis of the cross section of the ion beam 40. Herein, the workpiece 41 is moved along these scan lines in sequence. Further, to provide the first dose region 43 and the second dose region 45 with different doses, the step distance between neighboring scan lines, i.e., the scan path pitch of the raster pattern, can be different between the first raster pattern 42 and the second raster patter 44, also the first set of scan parameters' values can be different than the second set of scan parameters' values. Herein, potential scan parameters have at least the scan velocity, the scan times along same scan line, the ion beam current, the shape of the projected area, and so on.

Significantly, the different required doses of both the dose region 43 and the dose region 45 can be achieved by only adjusting one or more of the used raster pattern and the used set of scan parameters' values. Hence, no more extra step and no more extra device is required. Furthermore, when the width of a specific dose region is shorter than the long axis of the ion beam cross section but is longer than the short axis of the ion beam cross section, the above embodiments can almost not implant the ion bema outside the specific dose region, even implant into any neighboring dose region, during a period of scanning the specific dose region by the ion beam. Accordingly, the invention is more suitable for the dose split than the conventional two dimensional scan.

As usual, one or more of the ion beam, the raster pattern and other scan parameters' values can be adjusted so that different dose regions are formed by different ways. For example, by using different adjusted ion beams with different cross sections, by using same ion beam with different scan path pitches, or by using same adjusted ion beams with different scan parameters' values. Besides, to ensure the does uniformity of each dose region, it is popular to park the ion beam and/or the workpiece during a period that the ion beam is adjusted. Especially, park the ion beam and/or the workpiece when the ion beam is not implanted into the workpiece. Moreover, to simplify the adjustment of the ion beam, it is optional to use a variable aperture to adjust the ion beam before the workpiece is implanted by an adjusted ion beam. For example, by adjusting the shape and size of the variable aperture, the shape and the size of the cross section of the adjusted ion beam implanted into the workpiece is adjustable. Herein, how the ion beam current distribution is on the cross-section of the ion beam is not limited, it can be the popular Gaussian distribution or any other distribution. Furthermore, the value of each scan parameter, also the scan path pitch, is adjustable so that each dose region can have a specific dose. Particularly, to enhance the throughput, the scan path pitch of each raster pattern should be as large as possible. Indeed, the only limitation is that the dose uniformity of each dose region and the throughput of forming each dose region should be achieved simultaneously.

Although the above embodiments only show two dose regions on a workpiece, the invention is not limited by it. It is possible that six or eight mutually parallel spaced lines are used to define three or four dose regions on a workpiece. Also, it is possible that to form nine different adjusted dose regions on a workpiece by the following steps: (a) forming three dose regions with different doses on the workpiece by using the essential mechanism of the above embodiments, (b) rotate the workpiece an angle, such as a ninety degrees angle and (c) forming another three dose regions on the workpiece by using the essential mechanism of the above embodiments again. Hence, by superimposing the three dose regions and the another three dose regions, the nine different adjusted dose regions are formed. Further details f these steps are omitted because they are similar with how to form the nine different adjusted dose regions by using the conventional two dimensional scan. Additionally, although all the above embodiments move the workpiece along the raster pattern, the essential mechanism of the invention is not limited. It may be achieved by moving only the workpiece, moving only the ion beam or moving both the workpiece and the ion beam.

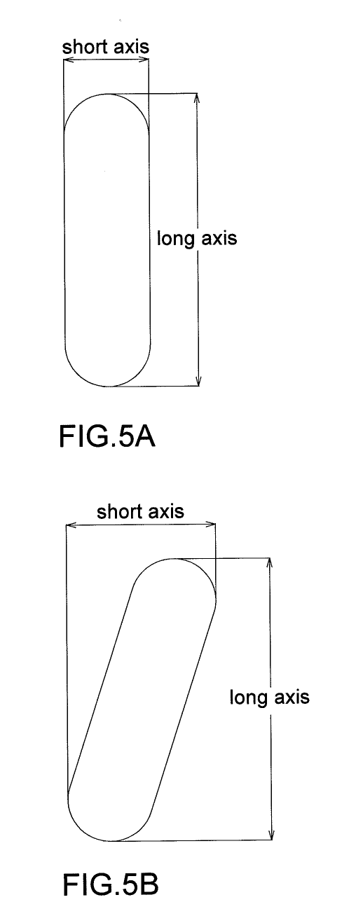

Finally, in the invention, the ion beam may be a ribbon ion beam or a spot ion beam. Indeed, how the shape of the cross section of the ion beam is not limited. If the cross section is not a circle, these are must a long axis and a short axis. If the cross section is a circle, the long axis and the short axis may be any two diameters mutually vertical to each other. To avoid any potential confusion and un-necessary limitation, FIG. 5A and FIG. 5B separately shows the schematic figures of two potential relations between a projected area (or a cross section of an ion beam) and the long/short axes. Clearly, the only requirement is the existence of both a long axis and a short axis, but not how to define the long axis and the short axis. In addition, the long axis and the short axis of the projected area are decided when the ion beam is totally projected on the workpiece, so as to prevent any potential confusion induced by deciding the long axis and the short axis of the projected area when the ion beam is at most partially implanted on the workpiece.

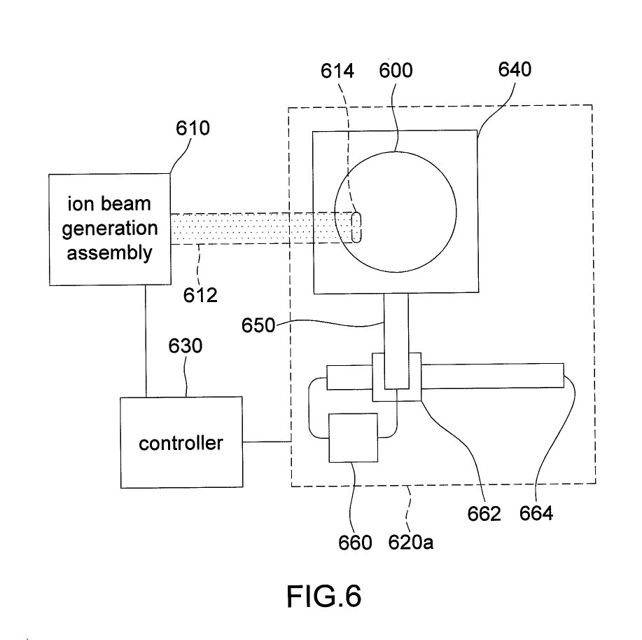

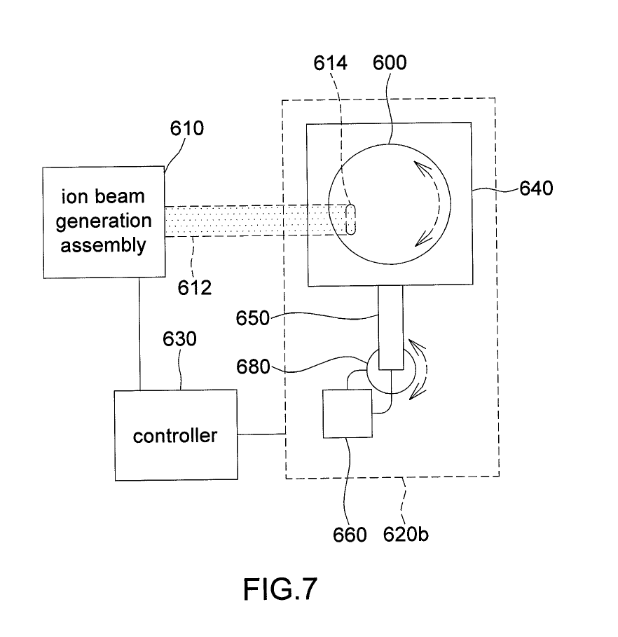

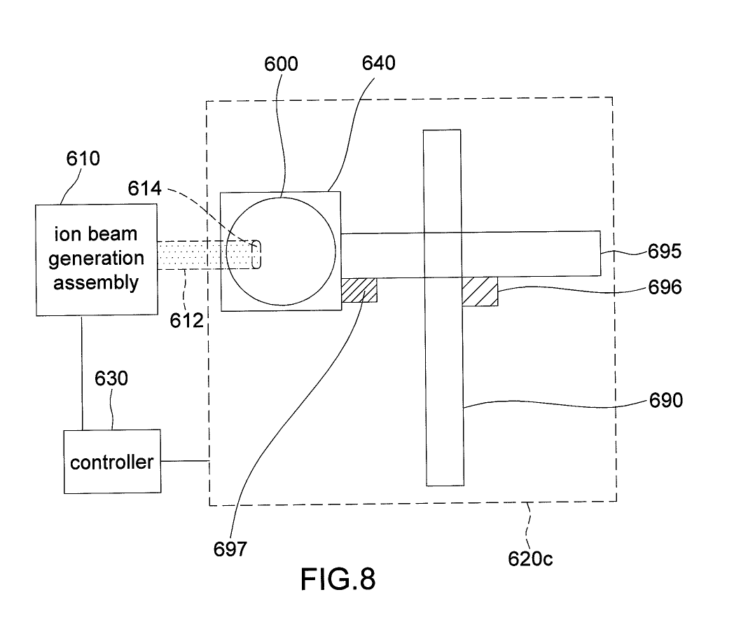

FIG. 6, FIG. 7 and FIG. 8 respectively illustrates the schematic view of an implanter according to three embodiments of the present invention. As shown in these figures, the implanter has at least an ion beam projection assembly 610, a movement assembly 620a (or 620b or 620c) and a controller 630. The ion beam projection assembly 610 is capable of providing an ion beam 612, and each of the movement assembly 620 a/b/c is capable of moving the workpiece 600. The controller 630 is capable of controlling one or more of the movement assembly 620 a/b/c and the ion beam projection assembly 610 so that one or more dose regions on the workpiece 600 are completely scanned by a projected area of the ion beam on the workpiece 600 by repeating the below steps: (a) move the projected area 614 along a first line essentially parallel to a long axis of the projected area 614 from an edge of the workpiece 600 of an opposite edge of the workpiece 600; and (b) shift the projected area 614 along a second line essentially parallel to a short axis of the projected area 614 by a shifted distance being not larger than a size of the short axis.

Furthermore, the controller 630 is limited only by its functions but not by how the functions are achieved. In other words, as example, the controller 630 may be a computer program code, a specific circuit, a firmware, an interface capable of receiving commends from external environment, or an application specific integrated circuit. Also, how to move the projected area 614 is not limited. It can be achieved by only moving the workpiece 600, by only deflecting the ion beam, or by move the workpiece 600 and deflecting the ion beam simultaneously.

In one embodiment as illustrated in FIG. 6 the movement assembly 620a has at least a holder 640, an extendable/retractable arm 650, a mechanical driver 660, an arm holder 662 and an arm 664. The holder 640 is used to hold the workpiece 600 and is fixed at a specific portion of the extendable/retractable arm 650, such as at an end of the extendable/retractable arm 650. And, a second specific portion, such as the other end, of the extendable/retractable arm 650 is fixed at the arm holder 662. Herein, the length of the extendable/retractable arm 650 can be flexibly changed so that the movement of the holder 640 can be achieved by simply changing the length of the extendable/retractable arm 650 without using an additional device to move the holder 640 along the extendable/retractable arm 650. Herein, the mechanical driver 660 is capable of moving the arm holder 662 along the arm 664. Herein, a practical configuration is that the extendable/retractable arm 650 is parallel to the long axis of the projected area 614 and the arm 664 is parallel to a short axis of the projected area 614. Therefore, the workpiece 600 held by the holder 640 can be moved along the long axis of the projected area 614 by only changing the length of the extendable/retractable arm 650, and can be moved along the short axis of projected area 614 by only moving the arm holder 662 along the arm 664.

In another embodiment as illustrated in FIG. 7, the implanter is similar to the implanter as illustrated in FIG. 6 but both the arm holder 662 and the arm 664 of the movement assembly 620a is replaced by a rotator 680 of the movement assembly 620b. Herein, the holder 640 is capable of rotating the workpiece 600, and the rotator 680 is capable of rotating the extendable/retractable arm 650 around a fixed point. Herein, two ends of the extendable/retractable arm 650 are fixed on holder 640 and the rotator 680 respectively so that the holder 640 can be rotated around the rotator 680. Accordingly, the workpiece 600 held by the holder 640 can be moved essentially along the long axis of the projected area 614 by slightly rotating both the extendable/retractable arm 650 and the holder 640 and significantly changing the length of the extendable/retractable arm 650 simultaneously. The workpiece 600 held by the holder 640 also can be moved essentially along the short axis by significantly rotating both the extendable/retractable arm 650 and holder 640 and slightly changing the length of the extendable/retractable arm 650 simultaneously. Note that the relative directions between the projected area 614 and the dose region on the workpiece 600 almost are changed when the workpiece 600 is rotated by the rotator 680. Hence, the rotation of the holder 640 can be used to correct the relative directions after the relative directions are changed by the rotation of the rotator 680.

In still another embodiment as illustrated in FIG. 8, the implanter is similar to the foregoing implanters expect that both the extendable/retractable arm 650 and related elements are replaced by both some righd arm 69 and related elements. Herein, the holder 640 is capable of holding the workpiece 600 and attached on a specific portion of a second rigid arm 695. Herein, the second rigid arm 695 is not parallel to the first rigid arm 690 and movable along the first rigid arm 690. Hence, the workpiece 600 can be moved along the long axis of the projected area 614 by only moving the second rigid arm 695 along the first right arm 690 and may be moved along the short axis of the projected area 614 by only moving the holder 640 along the second rigid arm 695. Of course, there are vertical driver 696 and horizontal driver 697 respectively used to move the second rigid arm 695 along the first rigid arm 690 and move the holder 640 along the second rigid arm 695. Herein, each of the vertical driver 696 and the horizontal driver 697 may has a motor, a power source, a gear wheal and a track. More details are omitted here because the combination of the first right arm 690 and the second rigid arm 695 is a well-known skill.

Although three examples of the implanter are disclosed above, the invention does not limit the details of the hardwares used to move the projected area over the workpiece. Indeed, the only limitation is how the projected area will be moved over the workpiece. Besides, although not particularly shown in FIG. 6 to FIG. 8, the proposed implanter may optionally have an aperture capable of adjusting the ion beam before the projected area 614 is formed on the workpiece 600. Hence, each dose region can be implanted respectively by an individually customized projected area with customized shape and customized size.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method of implanting a workpiece by an ion beam, comprising:
providing a workpiece and an ion beam, wherein said workpiece has a plurality of mutually parallel dose regions, wherein each said dose region has a long axis and a short axis;
projecting said ion beam on said workpiece to form a projected area of said ion beam on said workpiece, wherein said projected area has a long axis and a short axis;
moving said projected area along a first line essentially parallel to said long axis of said projected areas from an edge of said workpiece to an opposite edge of said workpiece;
shifting said projected area along a second line essentially parallel to said short axis of said short axis of said projected area, wherein a shifted distance is not larger than a size of said short axis of said specific projected area; and
repeating said moving step and said shifting steps in sequence until all said dose regions are completely scanned by said projected area.

2. The method as set forth in claim 1, wherein said ion beam is a ribbon ion beam or a spot ion beam.

3. The method as set forth in claim 1, wherein said long axis of said projected area is essentially parallel to said long axes of said dose regions and not shorter than said short axis of each said dose region.

4. The method as set forth in claim 1, further comprising separately adjusting said ion beam during a period of scanning said dose regions so that different said dose regions may be scanned by different said projected areas induced by different adjusted said ion beams.

5. The method as set forth in claim 4, further comprising parking said ion beam or said workpiece during a period of adjusting said ion beam.

6. The method as set forth in claim 4, further comprising using a variable aperture to separately adjust said ion beam before different said dose regions are separately scanned.

7. The method as set forth in claim 4, further comprising adjusting one or more scan parameters during a period of scanning said dose regions so that different said dose regions are separately scanned by different adjusted said ion beam.

8. The method as set forth in claim 7, wherein said scan parameters comprises scan velocity and scan path pitch.

9. A method of implanting a workpiece by an ion beam; comprising:
providing a workpiece and an ion beam, wherein said workpiece has a dose region shaped by two mutually parallel straight lines crossing said workpiece, wherein a cross section of said ion beam has a long axis and a short axis, wherein said long axis is shorter than a vertical distance between said mutually parallel straight lines;
moving said workpiece across said ion beam along a first line essentially parallel to said long axis;
shifting said workpiece along a second line essentially parallel to said short axis, wherein a shifted distance is not larger than a size of said short axis; and
repeating said moving step and said shifting step in sequence until whole said dose region is scanned by said ion beam.

10. The method as set forth in claim 9, wherein said ion beam is a ribbon ion beam or a spot ion beam.

11. The method as set forth in claim 9, wherein said mutually parallel straight lines are essentially parallel to said long axis of said cross section.

12. The method as set forth in claim 9, further comprising separately adjusting said ion beam during a period of scanning a plurality of said dose regions on said workpiece so that different said dose regions are implanted by different adjusted ion beams with different said cross sections.

13. The method as set forth in claim 12, further comprising parking said ion beam or said workpiece during a period of adjusting said ion beam.

14. The method as set forth in claim 12, further comprising using a variable aperture to separately adjust said ion beam before different said dose regions are separately scanned.

15. The method as set forth in claim 9, further comprising adjusting one or more scan parameters during a period of scanning a plurality of said dose regions on said workpiece so that different said dose regions are separately scanned, wherein said scan parameters comprises scan velocity and scan path pitch.

16. An implanter capable of implanting a workpiece by an ion beam, comprising:
an ion beam projection assembly capable of providing said ion beam;
a movement assembly capable of moving said workpiece; and
a controller capable of controlling one or more of said movement assembly and said ion beam projection assembly so that one or more dose regions on said workpiece are completely scanned by a projected area of said ion beam on said workpiece by repeating the below steps in sequence: moving said projected area along a first line essentially parallel to a long axis of said projected area from an edge of said workpiece to an opposite edge of said workpiece; and shifting said projected area along a second line essentially parallel to a short axis of said projected area by a shifted distance not larger than a size of said short axis.

17. The implanter as set forth in claim 16, said movement assembly comprising:
a holder capable of holding said workpiece;
an extendable/retractable arm capable of changing a length of said extendable/retractable arm essentially parallel to said long axis, wherein said holder is fixed at a first specific portion of said extendable/retractable arm so that said workpiece is moved along said long axis by only changing said length of said extendable/retractable arm; and
a mechanical driver capable of moving an arm holder along an arm essentially parallel to said short axis, wherein said extendable/retractable arm is fixed at said arm holder so that said workpiece is moved along said short axis by only moving said arm holder along said arm.

18. The implanter as set forth in claim 16, said movement assembly comprising:
a holder capable of holding and rotating said workpiece;
an extendable/retractable arm capable of changing a length of said extendable/retractable arm essentially parallel to said long axis; and
a rotator capable of rotating said extendable/retractable arm around a fixed point so that said workpiece is moved essentially along said long axis by slightly rotating both said extendable/retractable arm and said holder and significantly changing said length of said extendable/retractable arm simultaneously, also so that said workpiece is moved essentially along said short axis by significantly rotating both said extendable/retractable arm and said holder and slightly changing said length of said extendable/retractable arm simultaneously.

19. The implanter as set forth in claim 16, said movement assembly comprising:
a holder, capable of holding said workpiece;
a first rigid arm and an second rigid arm, wherein said second rigid arm is not parallel to said first rigid arm and movable along said first rigid arm; wherein said holder is attached on a specific portion of said second rigid arm so that said workpiece is moved along said long axis by only moving said second rigid arm along said right arm and is moved along said short axis by only moving said holder along said second rigid arm.

20. The implanter as set forth in claim 16, further comprising an aperture capable of adjusting said ion beam before said projected area is formed on said workpiece so that different said dose regions are scanned by different customized said projected areas.
